(19) United States
(12) Patent Application Publication
(10) Pub. No.: US 2023/0273654 A1
(43) Pub. Date: Aug. 31, 2023

(54) DUAL IN-LINE MEMORY MODULE COVER

(71) Applicant: Intel Corporation, Santa Clara, CA (US)

(72) Inventors: Xiang LI, Portland, OR (US); George VERGIS, Portland, OR (US); Phil GENG, Washougal, WA (US)

(21) Appl. No.: 18/195,072

(22) Filed: May 9, 2023

(51) Int. Cl. G06F 1/18

(52) U.S. Cl. CPC G06F 1/181; H05K 1/14

(57) ABSTRACT

A standalone top cover retention mechanism can attach to the top of an array of tall (e.g., 2U) DIMMs to provide structural support. In one example, the DIMM cover is attached to two or more DIMMs without attaching to the chassis. The DIMM cover can mitigate shock and vibration related failures at the DIMM level without significant interference with platform thermal mechanical solutions.

### FIELD OF THE INVENTION

Descriptions are generally related to computer memory, and more particular descriptions are related to memory module covers for structural failure mitigation.

### BACKGROUND OF THE INVENTION

The performance of computing systems is highly dependent on the performance of their system memory. Computing systems, such as desktop and server computing systems, often include a motherboard with memory module connectors in which memory modules can be installed to increase system memory capacity. One type of memory module is a dual in-line memory module (DIMM). DIMMs typically include memory devices mounted on a printed circuit board (PCB). The PCB includes conductive contacts for coupling with a connector on the motherboard.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” or examples are to be understood as describing a particular feature, structure, and/or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 illustrates a block diagram of an example of a 2U (2 unit) DIMM.

FIG. 2 illustrates an example of an array of DIMMs with a standalone cover.

FIGS. 3A-3F illustrate examples of DIMM covers with fasteners.

FIGS. 4A-4H illustrate examples of DIMM covers.

FIGS. 5A and 5B illustrate an example of a cover with dummy DIMMs.

FIG. 6 is a block diagram of an embodiment of a memory subsystem for which a standalone DIMM cover can be used.

FIG. 7 is a block diagram of an embodiment of a computing system that can include DIMMs with a standalone DIMM cover.

Descriptions of certain details and implementations follow, including a description of the figures, which may depict some or all of the embodiments described below, as well as discussing other potential embodiments or implementations of the inventive concepts presented herein.

### DETAILED DESCRIPTION

A stiffening cover for tall dual in-line memory modules (DIMMs) can provide support for structural failure mitigation.

Conventional DIMMs have various heights defined by standards, and typically fit within a 1U (“one unit” or “one rack unit”) system. For example, the DDR5 Load Reduced (LRDIMM) and Registered Dual Inline Memory Module (RDIMM) Common Specification (JESD305, published January 2022) defines the module height as 31.25 mm.

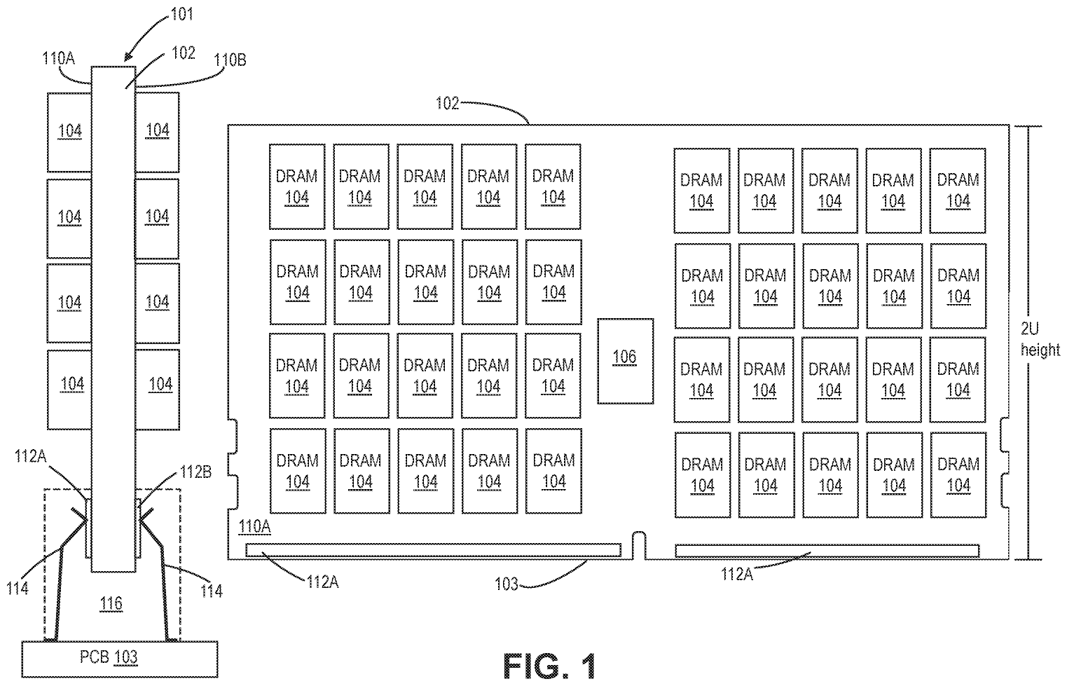

Increasing the height of a DIMM enables more memory chips to be mounted onto the faces of the DIMM, and thus enables an increase in memory capacity. FIG. 1 illustrates a block diagram of a 2U (“two unit”) DIMM 102 and a cross-sectional view 101 of the memory module 102 in a connector 116 on a PCB (e.g., a motherboard) 103. The DIMM 102 can be any of a variety of types DIMMs, such as an unbuffered or unregistered DIMM (UDIMM), a registered DIMM (RDIMM), a load reduced DIMM (LRDIMM), an enhanced load reduced DIMM (eLRDIMM) or other type of DIMM.

In one such example, the DIMM 102 and the DIMM connector 116 are compatible with a memory standard such as a double data rate synchronous dynamic random-access memory (DDR) standard, such as DDR3 (Double Data Rate version 3, original release by JEDEC (Joint Electronic Device Engineering Council) on Jun. 27, 2007), DDR4 (DDR version 4, originally published in September 2012 by JEDEC), DDR5 (DDR version 5, originally published in July 2020), DDR6, LPDDR3 (Low Power DDR version 3, JESD209-3B, August 2013 by JEDEC), LPDDR4 (LPDDR version 4, JESD209-4, originally published by JEDEC in August 2014), LPDDR5 (LPDDR version 5, JESD209-5A, originally published by JEDEC in January 2020), or others or combinations of memory technologies, and technologies based on derivatives or extensions of such specifications.

The DIMM 102 illustrated in FIG. 1 includes DRAM chips 104 on both faces or sides 110A, 110B of the DIMM 102. The DIMM 102 includes additional circuitry 106 such as a registered or registering clock driver (RCD), data buffers, power management integrated circuit (PMIC), and/or other circuitry. The DIMM 102 can be inserted or seated into the socket of a DIMM connector 116 on the motherboard 103. The connector 116 includes pins 114 that make contact with contacts (e.g., gold fingers) 112A, 112B on the front and back sides 110A, 110B of the DIMM 102. The gold fingers 112A, 112B are coupled with the DRAM chips 104 on the DIMM via conductive traces on or in the DIMM 102. In this way, signals can be transmitted to and from the DRAM chips 104 via the connector 116.

The DIMM in FIG. 1 is a tall DIMM (e.g., taller than conventional DIMMs) and can be considered a 2U DIMM having a 2U height. A 2U DIMM has a module height that is greater than a standard 1U DIMM. In one example, a 2U DIMM has at least twice the module height relative to a 1U DIMM. In one example, a 2U DIMM has a maximum height of 58 mm. In one example, the DIMM height is 58 mm. The 2U module height enables fitting more DRAM chips 104 on each side of the DIMM 102. Although the greater height of the 2U DIMMs enables greater memory capacity, DIMMs that are significantly taller than conventional DIMMs have a heavier mass that increases the structural risk at the board and system level during shipping, handling, and in operation. In one example, compared to a standard 1U DDR DIMM, a 2U DIMM may nearly double the height of the center of gravity. With the increase in DIMM mass, the 2U DIMM shock and vibration risk increases and can potentially cause the 2U DIMMs to fail structural testing.

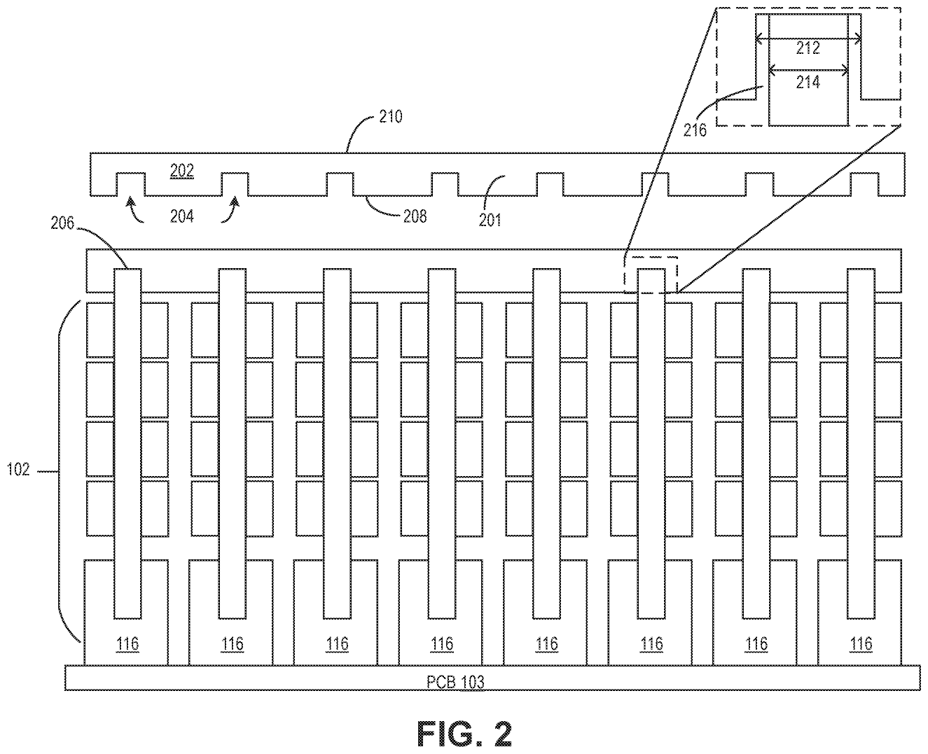

A standalone top cover retention mechanism can attach to the top of an array of tall (e.g., 2U) DIMMs to provide structural support. In one example, the DIMM cover is attached to two or more DIMMs without attaching to the chassis. The DIMM cover can mitigate shock and vibration related failures at the DIMM level without significant interference with platform thermal mechanical solutions. FIG. 2 illustrates an example of a cross-sectional view of an array of DIMMs 102 with a standalone DIMM cover 201. As can be seen in FIG. 2, a cover 201 is secured over the top edges of the DIMMs 102 to hold the DIMMs 102 together to enforce a stable structure.

The cover includes a rigid body 202 with a top side 210 and a bottom side 208. When secured over the DIMMs 102, the bottom side 208 of the cover 201 is facing the DIMMs 102. The cover 201 includes a plurality of grooves 204 in the bottom 208 of the rigid body 202 to receive top edges 206 of the plurality of DIMMs 102. The grooves 204 are openings or spaces (such as slots, notches, or recesses) into which the top edges 206 of the DIMMs 102 can fit when the cover 201 is secured over the DIMMs 102. Thus, in one example, when the cover 201 is secured on the array of DIMMs 102, portions of the rigid body 202 between adjacent grooves extend partially down the sides of the DIMMs. In one example, each of the grooves has a width 212 that is greater than the thickness 214 of the DIMM 102. In one such example, the width 212 of the grooves is slightly greater than the thickness 214 of the DIMMs to allow for a small space 216 on one or both sides of the DIMMs 102. In one example, the cover 201 includes one or more grooves corresponding with every DIMM 102 in the array. For example, if the cover is for securing four DIMMs, the cover can include four grooves (e.g., in a solid cover), each sized to receive a single DIMM. In one example, the grooves 204 of the cover 201 have a rectangular (i.e., approximately or substantially rectangular) shape to receive the top edges of the DIMMs 102.

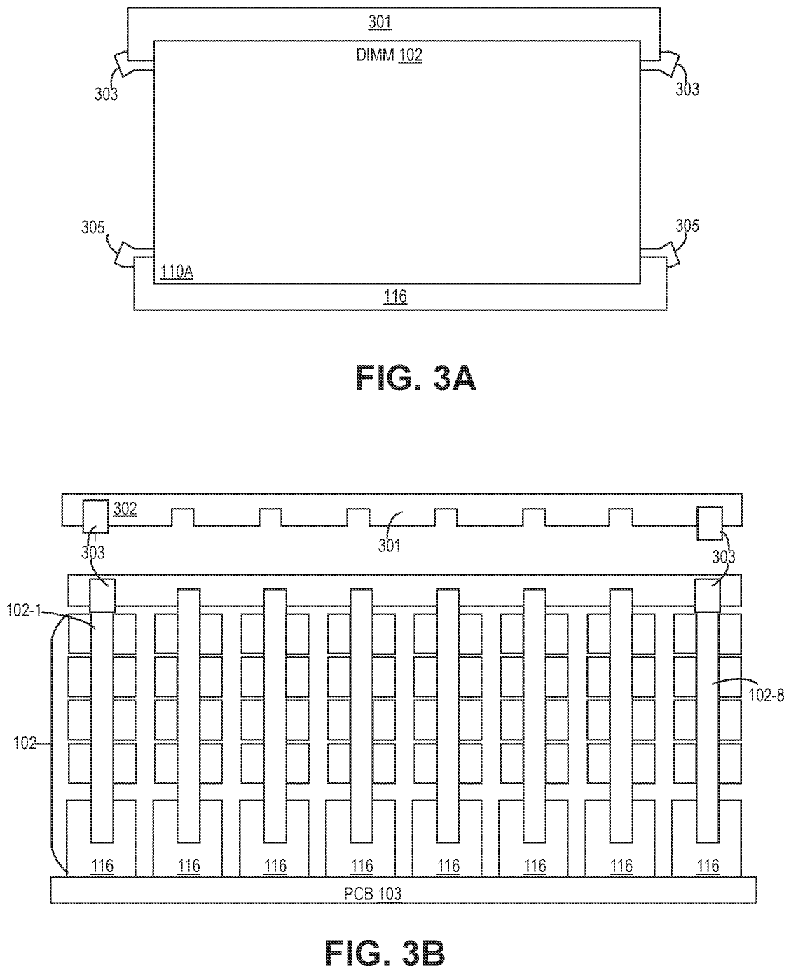

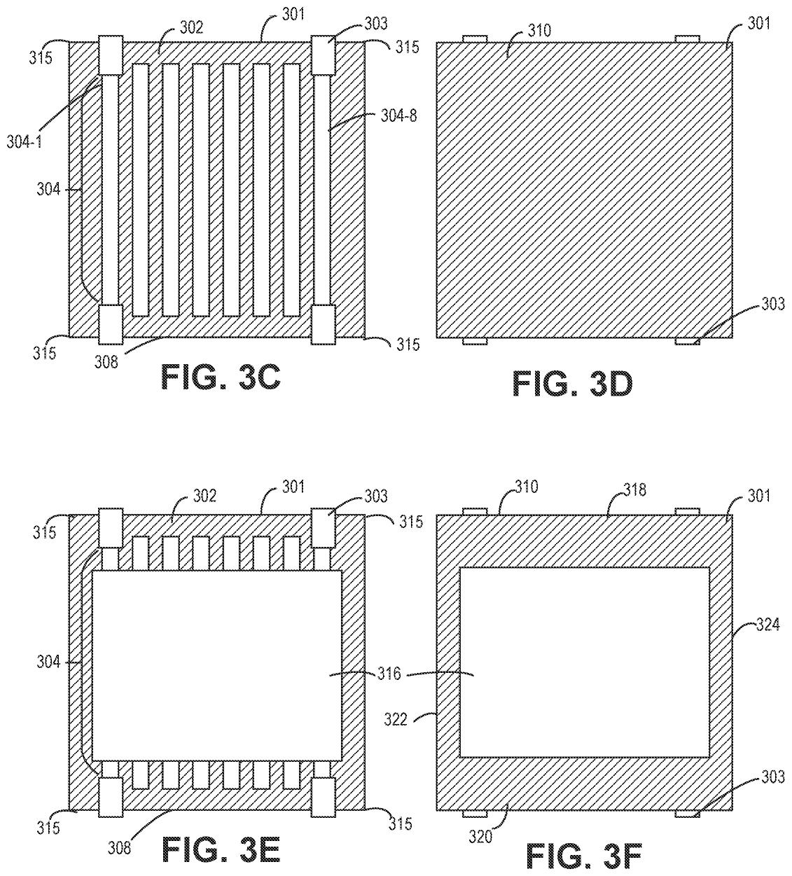

The cover 201 includes a standalone rigid body 202. The rigid body 202 is formed from a material that provides sufficient structural support to the DIMMs 102, such as plastic, metal, or other stiff or rigid material. The rigid body 202 is standalone in the sense that it is not attached to the chassis or other housing or case in which the array of DIMMs 102 is housed. Instead, in one example, the cover 201 is secured to one or more of the DIMMs 102 with one or more fasteners. For example, for a cover with four corners, the cover 201 can be latched to two of the DIMMs 102 at four corners of the cover 201. For example, FIGS. 3A-3D illustrate an example of a cover 301 with fasteners 303 at four corners of the DIMM cover. FIG. 3A illustrates a cross-sectional view showing a side 110A of a DIMM 102 with the DIMM cover 301. FIG. 3B illustrates a cross-sectional view showing side edges of an array of DIMMs 102 with the DIMM cover 301. FIGS. 3C-3F illustrate bottom and top views of examples of the DIMM cover 301.

Turning first to FIGS. 3A and 3B, the cover 301 includes fasteners 303 to secure the standalone rigid body 302 over the plurality of DIMMs 102. The cover 301 can include any attachment mechanism to attach the cover 301 to one or more of the DIMMs to secure the cover 301 in place. Examples of attachment mechanisms include latches, screws, snap attachment mechanisms, or other mechanisms for securing the cover 301 in place. In one example, the cover includes end latches that are similar to or the same as latches of a DIMM connector (e.g., the same or similar to the latches 305). In one example, the grooves in the bottom of the cover 301 are sufficiently deep to secure the cover in place by insertion of the top edges of the DIMMs 102 into the grooves without a separate fastener.

In one example, the fasteners are positioned proximate to the outer corners of only the outer DIMMs 102-1 and 102-8 in an array (or sub-array) or DIMMs. For example, the cover includes one or two latches to latch onto the first DIMM 102-1 and the last DIMM 102-8 in an array, but not the DIMMs between the first and last DIMMs 102-1, 102-8. In other examples, the cover can include fasteners to attach to each DIMM secured by the cover, or some of the DIMMs secured by the cover (e.g., inner and/or outer DIMMs in the array).

FIG. 3C and 3D illustrate bottom and top views of the DIMM cover 301 without DIMMs. The cover 301 in FIGS. 3C and 3D includes a solid top 310 (e.g., without cutouts or openings to expose the DIMMs from the top). As can be seen in the example of FIG. 3C, the bottom side 308 of the cover includes the plurality of grooves 304 to receive top edges of DIMMs. The cover 301 in FIGS. 3C and 3D includes four fasteners 303, one fastener proximate to each of the four corners 315 of the standalone rigid body 302. In the illustrated example, the fasteners 303 are thus proximate to the outer grooves 304-1 and 304-8.

FIGS. 3E and 3F illustrate bottom and top views of the cover 301 with an opening 316. Unlike the cover 301 of FIGS. 3C and 3D, the cover 301 of FIGS. 3E and 3F includes an opening 316 between opposing sides (e.g., between opposing sides 318, 320 and opposing sides 322, 324) of the rigid body 302 to expose the partially covered plurality of DIMMs. Like FIGS. 3C and 3D, the cover 301 of FIGS. 3E and 3F includes grooves 304 to receive the top edges of DIMMs. However, due to the opening 316 in the middle of the rigid body 302, the grooves 304 can be considered pairs of grooves for receiving opposite ends of the DIMMs. Thus, in the example illustrated in FIG. 3E, the cover 301 includes two grooves (one on each of the opposing sides 318 and 320) to receive each DIMM. Also like FIGS. 3C and 3D, the cover 301 of FIGS. 3E and 3F includes four fasteners 303, one fastener proximate to each of the four corners 315 of the standalone rigid body 302.

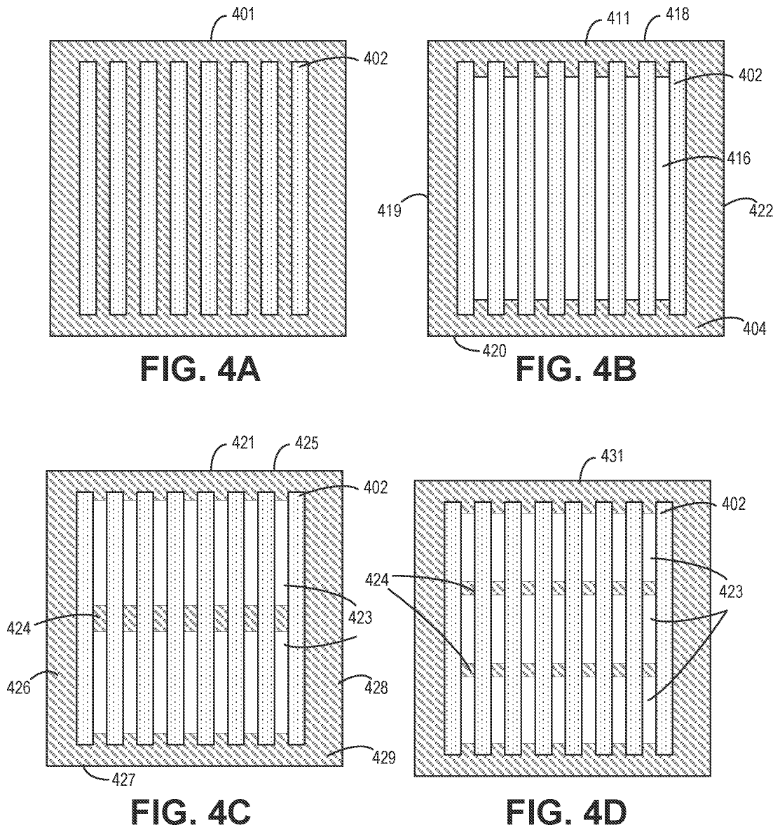

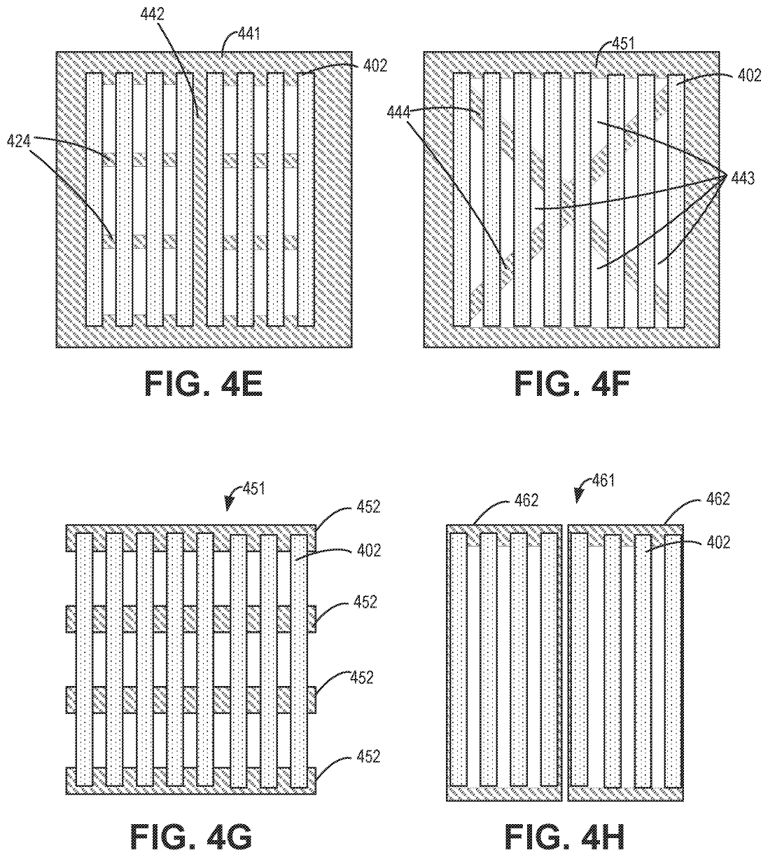

FIGS. 4A-4H illustrate examples of DIMM covers with different configurations. Note FIGS. 4A-4H show bottom-up views of covers secured over DIMMs 402.

FIG. 4A illustrates a solid cover 401 without openings or cutouts to expose the DIMMs 402. The cover 401 completely covers the DIMMs 402 over which the cover 401 is secured. The cover 401 has the benefit of securing the DIMMs 402 along their entire length. In contrast, FIG. 4B illustrates a cover 411 with a single opening 416. In one example, one or more openings in a DIMM cover reduces the cover's mass while maintaining the structural stiffness. A cover with one or more openings that partially expose the DIMMs has the benefit of improving air circulation around the DIMMs. In the example illustrated in FIG. 4B, the standalone rigid body 404 of the cover 411 includes or forms a frame over the DIMMs 402. The example in FIG. 4B includes four sides 418, 419, 420, 422. The four sides of the cover 411 include two opposing sides 418, 420 that are perpendicular to the DIMMs 402 (and thus perpendicular to grooves of the cover to receive the DIMMs 402), and two opposing sides 419, 422 that are parallel to the DIMMs 402 (and thus parallel to the groves to receive the DIMMs 402). Thus, the standalone rigid body 404 of the cover 411 includes four sides 418, 419, 420, and 422 that form a frame with the opening 416 at its middle.

FIGS. 4C and 4D illustrate covers 421 and 431 with multiple openings 423. Like the example in FIG. 4B, the covers 421 and 431 have the benefit of improved air flow around the DIMMs 402 compared to a solid cover. However, in addition to the plurality of openings 423 between opposing sides of the rigid body (e.g., between opposing sides 425, 427 and opposing sides 426, 428 of the rigid body 429), the cover 421 includes one or more supports 424 extending along an axis perpendicular to a length of the plurality of DIMMs 402 and perpendicular to the grooves to receive the DIMMs 402. Although the examples of FIGS. 4C and 4D depict one and two perpendicular supports respectively, other examples include covers having more than two perpendicular supports.

Other examples may include supports along axes parallel to, perpendicular to, and/or diagonal to the DIMMs and DIMM-receiving grooves of the cover. For example, FIG. 4E illustrates an example of a cover 441 with two perpendicular supports 424 and a parallel support 442. Thus, the cover 441 includes supports along two orthogonal axes. FIG. 4F illustrates an example of a cover 451 with two diagonal supports 444. Thus, the cover 451 includes a plurality of openings 443 and supports 444 that are at an angle relative to the sides of the cover (and relative to the DIMM-grooves of the cover) that is less than 90 degrees.

Accordingly, FIGS. 4C-4F show some examples of supports and openings in DIMM covers; however, the cover can include one or more supports extending along one or more axes, including: a first axis perpendicular to a length of the plurality of DIMMs, a second axis parallel to the length of the plurality of DIMMs, and a third axis diagonal relative to the length of the plurality of DIMMs.

FIG. 4G illustrates an example of a cover 451 that includes multiple discrete rigid bodies 452, each of which is to secure and at least partially cover a plurality of DIMMs (the same or different plurality of DIMMs in an array). In the illustrated example, each of the discrete rigid bodies 452 extend perpendicular to the DIMMs 402 to secure the DIMMs 402 at a different point along the length of the DIMMs 402. Although four discrete rigid bodies 452 are shown, two, three, or more than four discrete rigid bodies can be used to secure the DIMMs 402.

FIG. 4H illustrates another example of a cover 461 that includes multiple discrete rigid bodies 462. In the example illustrated in FIG. 4H, each of the discrete rigid bodies 462 are similar to or the same as the frame-shaped cover 411 of FIG. 4B. Thus, DIMM covers can have a variety of shapes and configurations to mitigate shock and vibration related failures at the DIMM and system level.

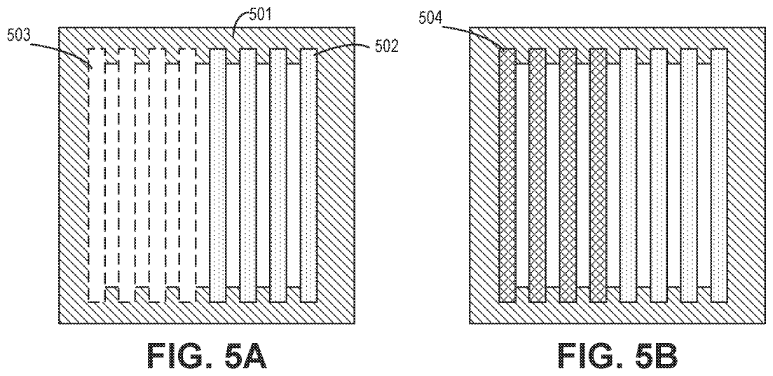

FIGS. 5A and 5B illustrate an example of dummy DIMMs to facilitate use a cover in a system with fewer DIMMs than are supported by the cover. FIG. 5A shows a DIMM cover 501 that is configured to secure eight DIMMs. However, only four DIMMs 502 are present in the system (dashed line boxes 503 indicate absent DIMMs). In order to provide improved structural support with the cover 501 in such circumstances, dummy DIMMs 504 can be inserted into the unused DIMM slots, as shown in FIG. 5B. A dummy DIMM is a non-operational DIMM-shaped card or apparatus, which can enable additional support with a cover 501.

Thus, a standalone DIMM cover such as those disclosed herein can hold multiple DIMMs together to stiffen the structure and to stabilize individual DIMM deflections. A standalone cover can prevent significant 2U DIMM deflection and DIMM continuity failures related to shock and vibration conditions. Additionally, a standalone DIMM cover can mitigate connector latch breakage, J-lead pullout, and solder joint crack risks under shock and vibration loads. According to examples, top cover retention creates an air flow channel for better thermal dissipation. The standalone cover also enables improved serviceability due to the lack of an attachment to the chassis system.

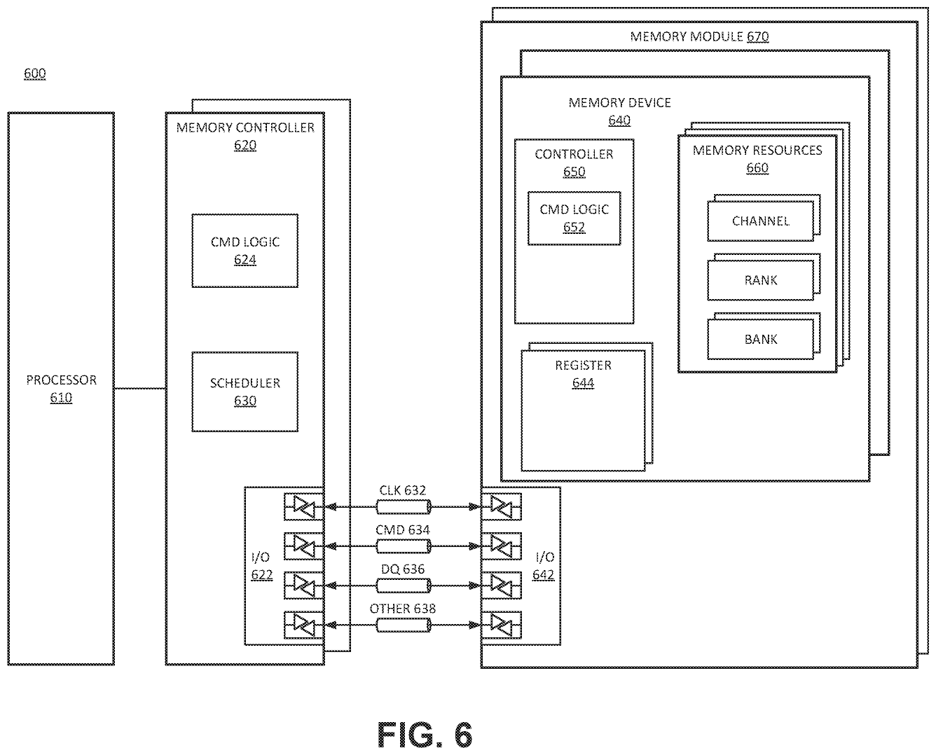

FIG. 6 is a block diagram of an embodiment of a memory subsystem for which a standalone DIMM cover can be used. System 600 includes a processor and elements of a memory subsystem in a computing device. Processor 610 represents a processing unit of a computing platform that may execute an operating system (OS) and applications, which can collectively be referred to as the host or the user of the memory. The OS and applications execute operations that result in memory accesses. Processor 610 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 600 can be implemented as an SOC (system on a chip) or be implemented with standalone components.

Reference to memory devices can apply to different memory types. Memory devices often refers to volatile memory technologies. Volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, originally published in September 2012 by JEDEC), DDR5 (DDR version 5, originally published in July 2020), LPDDR3 (Low Power DDR version 3, JESD209-3B, August 2013 by JEDEC), LPDDR4 (LPDDR version 4, JESD209-4, originally published by JEDEC in August 2014), LPDDR5 (LPDDR version 5, JESD209-5A, originally published by JEDEC in January 2020), WIO2 (Wide Input/Output version 2, JESD229-2 originally published by JEDEC in August 2014), HBM (High Bandwidth Memory, JESD235, originally published by JEDEC in October 2013), HBM2 (HBM version 2, JESD235C, originally published by JEDEC in January 2020), or HBM3 (HBM version 3 currently in discussion by JEDEC), or others or combinations of memory technologies, and technologies based on derivatives or extensions of such specifications. The JEDEC standards are available at www.jedec.org.

Descriptions herein referring to a “RAM” or “RAM device” can apply to any memory device that allows random access, whether volatile or nonvolatile. Descriptions referring to a “DRAM” or a “DRAM device” can refer to a volatile random access memory device. The memory device or DRAM can refer to the die itself, to a packaged memory product that includes one or more dies, or both. In one embodiment, a system with volatile memory that needs to be refreshed can also include nonvolatile memory.

Memory controller 620 represents one or more memory controller circuits or devices for system 600. Memory controller 620 represents control logic that generates memory access commands in response to the execution of operations by processor 610. Memory controller 620 accesses one or more memory devices 640. Memory devices 640 can be DRAM devices in accordance with any referred to above. In one embodiment, memory devices 640 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one embodiment, settings for each channel are controlled by separate mode registers or other register settings. In one embodiment, each memory controller 620 manages a separate memory channel, although system 600 can be configured to have multiple channels managed by a single controller, or to have multiple controllers on a single channel. In one embodiment, memory controller 620 is part of host processor 610, such as logic implemented on the same die or implemented in the same package space as the processor.

Memory controller 620 includes I/O interface logic 622 to couple to a memory bus, such as a memory channel as referred to above. I/O interface logic 622 (as well as I/O interface logic 642 of memory device 640) can include pins, pads, connectors, signal lines, traces, or wires, or other hardware to connect the devices, or a combination of these. I/O interface logic 622 can include a hardware interface. As illustrated, I/O interface logic 622 includes at least drivers/transceivers for signal lines. Commonly, wires within an integrated circuit interface couple with a pad, pin, or connector to interface signal lines or traces or other wires between devices. I/O interface logic 622 can include drivers, receivers, transceivers, or termination, or other circuitry or combinations of circuitry to exchange signals on the signal lines between the devices. The exchange of signals includes at least one of transmit or receive. While shown as coupling I/O 622 from memory controller 620 to I/O 642 of memory device 640, it will be understood that in an implementation of system 600 where groups of memory devices 640 are accessed in parallel, multiple memory devices can include I/O interfaces to the same interface of memory controller 620. In an implementation of system 600 including one or more memory modules 670, I/O 642 can include interface hardware of the memory module in addition to interface hardware on the memory device itself. Other memory controllers 620 will include separate interfaces to other memory devices 640.

The bus between memory controller 620 and memory devices 640 can be implemented as multiple signal lines coupling memory controller 620 to memory devices 640. The bus may typically include at least clock (CLK) 632, command/address (CMD) 634, and write data (DQ) and read data (DQ) 636, and zero or more other signal lines 638. In one embodiment, a bus or connection between memory controller 620 and memory can be referred to as a memory bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one embodiment, independent channels have different clock signals, C/A buses, data buses, and other signal lines. Thus, system 600 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 620 and memory devices 640. An example of a serial bus technology is 8B10B encoding and transmission of high-speed data with embedded clock over a single differential pair of signals in each direction. In one embodiment, CMD 634 represents signal lines shared in parallel with multiple memory devices. In one embodiment, multiple memory devices share encoding command signal lines of CMD 634, and each has a separate chip select (CS_n) signal line to select individual memory devices.

It will be understood that in the example of system 600, the bus between memory controller 620 and memory devices 640 includes a subsidiary command bus CMD 634 and a subsidiary bus to carry the write and read data, DQ 636. In one embodiment, the data bus can include bidirectional lines for read data and for write/command data. In another embodiment, the subsidiary bus DQ 636 can include unidirectional write signal lines for write and data from the host to memory and can include unidirectional lines for read data from the memory to the host. In accordance with the chosen memory technology and system design, other signals 638 may accompany a bus or sub bus, such as strobe lines DQS. Based on design of system 600, or implementation if a design supports multiple implementations, the data bus can have more or less bandwidth per memory device 640. For example, the data bus can support memory devices that have either a x32 interface, a x16 interface, a x8 interface, or other interface. The convention “xW,” where W is an integer that refers to an interface size or width of the interface of memory device 640, which represents a number of signal lines to exchange data with memory controller 620. The interface size of the memory devices is a controlling factor on how many memory devices can be used concurrently per channel in system 600 or coupled in parallel to the same signal lines. In one embodiment, high bandwidth memory devices, wide interface devices, or stacked memory configurations, or combinations, can enable wider interfaces, such as a x128 interface, a x256 interface, a x512 interface, a x1024 interface, or other data bus interface width.

In one embodiment, memory devices 640 and memory controller 620 exchange data over the data bus in a burst, or a sequence of consecutive data transfers. The burst corresponds to a number of transfer cycles, which is related to a bus frequency. In one embodiment, the transfer cycle can be a whole clock cycle for transfers occurring on a same clock or strobe signal edge (e.g., on the rising edge). In one embodiment, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length 8 (BL8), and each memory device 640 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 640 represent memory resources for system 600. In one embodiment, each memory device 640 is a separate memory die. In one embodiment, each memory device 640 can interface with multiple (e.g., 2) channels per device or die. Each memory device 640 includes I/O interface logic 642, which has a bandwidth determined by the implementation of the device (e.g., x16 or x8 or some other interface bandwidth). I/O interface logic 642 enables the memory devices to interface with memory controller 620. I/O interface logic 642 can include a hardware interface and can be in accordance with I/O 622 of memory controller, but at the memory device end. In one embodiment, multiple memory devices 640 are connected in parallel to the same command and data buses. In another embodiment, multiple memory devices 640 are connected in parallel to the same command bus and are connected to different data buses. For example, system 600 can be configured with multiple memory devices 640 coupled in parallel, with each memory device responding to a command, and accessing memory resources 660 internal to each. For a Write operation, an individual memory device 640 can write a portion of the overall data word, and for a Read operation, an individual memory device 640 can fetch a portion of the overall data word. As non-limiting examples, a specific memory device can provide or receive, respectively, 8 bits of a 128-bit data word for a Read or Write transaction, or 8 bits or 16 bits (depending for a x8 or a x16 device) of a 256-bit data word. The remaining bits of the word will be provided or received by other memory devices in parallel.

In one embodiment, memory devices 640 are disposed directly on a motherboard or host system platform (e.g., a PCB (printed circuit board) on which processor 610 is disposed) of a computing device. In one embodiment, memory devices 640 can be organized into memory modules 670. In one embodiment, memory modules 670 represent dual inline memory modules (DIMMs). In one such example, the memory modules include tall (e.g., 2U) DIMMs with a standalone DIMM cover in accordance with examples described herein.

In one embodiment, memory modules 670 represent other organization of multiple memory devices to share at least a portion of access or control circuitry, which can be a separate circuit, a separate device, or a separate board from the host system platform. Memory modules 670 can include multiple memory devices 640, and the memory modules can include support for multiple separate channels to the included memory devices disposed on them. In another embodiment, memory devices 640 may be incorporated into the same package as memory controller 620, such as by techniques such as multi-chip-module (MCM), package-on-package, through-silicon via (TSV), or other techniques or combinations. Similarly, in one embodiment, multiple memory devices 640 may be incorporated into memory modules 670, which themselves may be incorporated into the same package as memory controller 620. It will be appreciated that for these and other embodiments, memory controller 620 may be part of host processor 610.

Memory devices 640 each include memory resources 660. Memory resources 660 represent individual arrays of memory locations or storage locations for data. Typically, memory resources 660 are managed as rows of data, accessed via wordline (rows) and bitline (individual bits within a row) control. Memory resources 660 can be organized as separate channels, ranks, and banks of memory. Channels may refer to independent control paths to storage locations within memory devices 640. A rank refers to memory devices coupled with the same chip select. Ranks may refer to common locations across multiple memory devices (e.g., same row addresses within different devices). Banks may refer to arrays of memory locations within a memory device 640. In one embodiment, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one embodiment, memory devices 640 include one or more registers 644. Register 644 represents one or more storage devices or storage locations that provide configuration or settings for the operation of the memory device. In one embodiment, register 644 can provide a storage location for memory device 640 to store data for access by memory controller 620 as part of a control or management operation. In one embodiment, register 644 includes one or more Mode Registers. In one embodiment, register 644 includes one or more multipurpose registers. The configuration of locations within register 644 can configure memory device 640 to operate in different “modes,” where command information can trigger different operations within memory device 640 based on the mode. Additionally, or in the alternative, different modes can also trigger different operation from address information or other signal lines depending on the mode. Settings of register 644 can indicate configuration for I/O settings (e.g., timing, termination or ODT (on-die termination), driver configuration, or other I/O settings).

Memory device 640 includes controller 650, which represents control logic within the memory device to control internal operations within the memory device. For example, controller 650 decodes commands sent by memory controller 620 and generates internal operations to execute or satisfy the commands. Controller 650 can be referred to as an internal controller and is separate from memory controller 620 of the host. Controller 650 can determine what mode is selected based on register 644 and configure the internal execution of operations for access to memory resources 660 or other operations based on the selected mode. Controller 650 generates control signals to control the routing of bits within memory device 640 to provide a proper interface for the selected mode and direct a command to the proper memory locations or addresses. Controller 650 includes command logic 652, which can decode command encoding received on command and address signal lines. Thus, command logic 652 can be or include a command decoder. With command logic 652, memory device can identify commands and generate internal operations to execute requested commands.

Referring again to memory controller 620, memory controller 620 includes command (CMD) logic 624, which represents logic or circuitry to generate commands to send to memory devices 640. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 640, memory controller 620 can issue commands via I/O 622 to cause memory device 640 to execute the commands. In one embodiment, controller 650 of memory device 640 receives and decodes command and address information received via I/O 642 from memory controller 620. Based on the received command and address information, controller 650 can control the timing of operations of the logic and circuitry within memory device 640 to execute the commands. Controller 650 is responsible for compliance with standards or specifications within memory device 640, such as timing and signaling requirements. Memory controller 620 can implement compliance with standards or specifications by access scheduling and control.

Memory controller 620 includes scheduler 630, which represents logic or circuitry to generate and order transactions to send to memory device 640. From one perspective, the primary function of memory controller 620 could be said to schedule memory access and other transactions to memory device 640. Such scheduling can include generating the transactions themselves to implement the requests for data by processor 610 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 620 typically includes logic such as scheduler 630 to allow selection and ordering of transactions to improve performance of system 600. Thus, memory controller 620 can select which of the outstanding transactions should be sent to memory device 640 in which order, which is typically achieved with logic much more complex that a simple first-in first-out algorithm. Memory controller 620 manages the transmission of the transactions to memory device 640, and manages the timing associated with the transaction. In one embodiment, transactions have deterministic timing, which can be managed by memory controller 620 and used in determining how to schedule the transactions with scheduler 630.

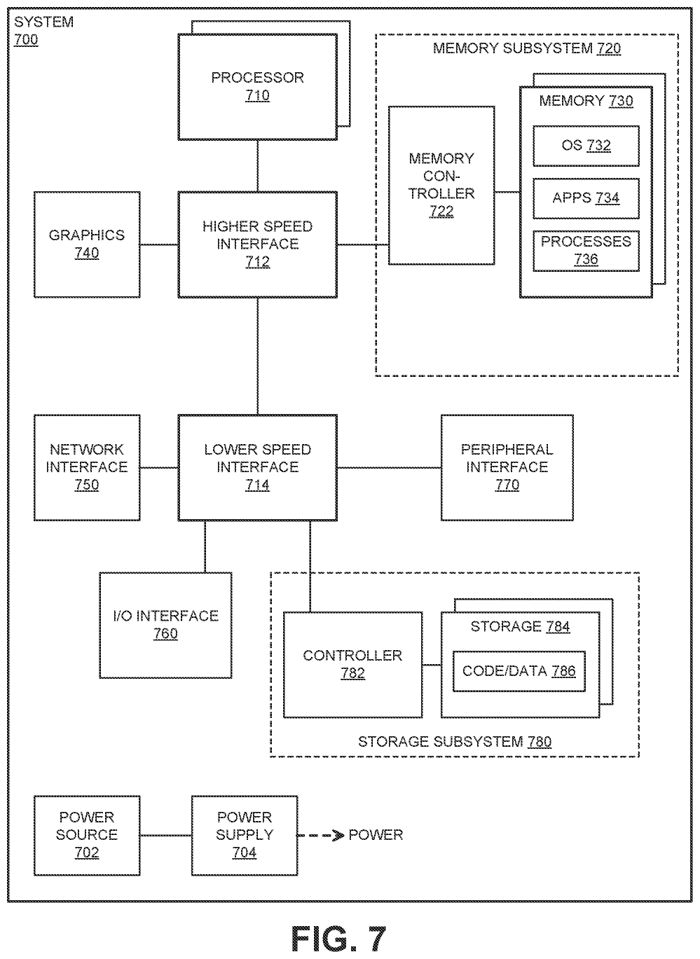

FIG. 7 is a block diagram of an embodiment of a computing system that can include DIMMs with a standalone DIMM cover. System 700 represents a computing device in accordance with any embodiment described herein, and can be a laptop computer, a desktop computer, a tablet computer, a server, a gaming or entertainment control system, a scanner, copier, printer, routing or switching device, embedded computing device, a smartphone, a wearable device, an internet-of-things device, or other electronic device.

System 700 includes processor 710, which provides processing, operation management, and execution of instructions for system 700. Processor 710 can include any type of microprocessor, central processing unit (CPU), graphics processing unit (GPU), processing core, or other processing hardware to provide processing for system 700, or a combination of processors. Processor 710 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one embodiment, system 700 includes interface 712 coupled to processor 710, which can represent a higher speed interface or a high throughput interface for system components that needs higher bandwidth connections, such as memory subsystem 720 or graphics interface components 740. Interface 712 represents an interface circuit, which can be a standalone component or integrated onto a processor die. Where present, graphics interface 740 interfaces to graphics components for providing a visual display to a user of system 700. In one embodiment, graphics interface 740 can drive a high definition (HD) display that provides an output to a user. High definition can refer to a display having a pixel density of approximately 100 PPI (pixels per inch) or greater and can include formats such as full HD (e.g., 1080 p), retina displays, 4K (ultra-high definition or UHD), or others. In one embodiment, the display can include a touchscreen display. In one embodiment, graphics interface 740 generates a display based on data stored in memory 730 or based on operations executed by processor 710 or both. In one embodiment, graphics interface 740 generates a display based on data stored in memory 730 or based on operations executed by processor 710 or both.

Memory subsystem 720 represents the main memory of system 700 and provides storage for code to be executed by processor 710, or data values to be used in executing a routine. Memory subsystem 720 can include one or more memory devices 730 such as read-only memory (ROM), flash memory, one or more varieties of random-access memory (RAM) such as DRAM, or other memory devices, or a combination of such devices. Memory 730 stores and hosts, among other things, operating system (OS) 732 to provide a software platform for execution of instructions in system 700. Additionally, applications 734 can execute on the software platform of OS 732 from memory 730. Applications 734 represent programs that have their own operational logic to perform execution of one or more functions. Processes 736 represent agents or routines that provide auxiliary functions to OS 732 or one or more applications 734 or a combination. OS 732, applications 734, and processes 736 provide software logic to provide functions for system 700. In one embodiment, memory subsystem 720 includes memory controller 722, which is a memory controller to generate and issue commands to memory 730. It will be understood that memory controller 722 could be a physical part of processor 710 or a physical part of interface 712. For example, memory controller 722 can be an integrated memory controller, integrated onto a circuit with processor 710.

While not specifically illustrated, it will be understood that system 700 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus.

In one embodiment, system 700 includes interface 714, which can be coupled to interface 712. Interface 714 can be a lower speed interface than interface 712. In one embodiment, interface 714 represents an interface circuit, which can include standalone components and integrated circuitry. In one embodiment, multiple user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB (universal serial bus), or other wired or wireless standards-based or proprietary interfaces. Network interface 750 can exchange data with a remote device, which can include sending data stored in memory or receiving data to be stored in memory.

In one embodiment, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include any hardware interface not specifically mentioned above. Peripherals refer generally to devices that connect dependently to system 700. A dependent connection is one where system 700 provides the software platform or hardware platform or both on which operation executes, and with which a user interacts.

In one embodiment, system 700 includes storage subsystem 780 to store data in a nonvolatile manner. In one embodiment, in certain system implementations, at least certain components of storage 780 can overlap with components of memory subsystem 720. Storage subsystem 780 includes storage device(s) 784, which can be or include any conventional medium for storing large amounts of data in a nonvolatile manner, such as one or more magnetic, solid state, or optical based disks, or a combination. Storage 784 holds code or instructions and data 786 in a persistent state (i.e., the value is retained despite interruption of power to system 700). Storage 784 can be generically considered to be a “memory,” although memory 730 is typically the executing or operating memory to provide instructions to processor 710. Whereas storage 784 is nonvolatile, memory 730 can include volatile memory (i.e., the value or state of the data is indeterminate if power is interrupted to system 700). In one embodiment, storage subsystem 780 includes controller 782 to interface with storage 784. In one embodiment controller 782 is a physical part of interface 714 or processor 710 or can include circuits or logic in both processor 710 and interface 714.

Power source 702 provides power to the components of system 700. More specifically, power source 702 typically interfaces to one or multiple power supplies 704 in system 700 to provide power to the components of system 700. In one embodiment, power supply 704 includes an AC to DC (alternating current to direct current) adapter to plug into a wall outlet. Such AC power can be renewable energy (e.g., solar power) power source 702. In one embodiment, power source 702 includes a DC power source, such as an external AC to DC converter. In one embodiment, power source 702 or power supply 704 includes wireless charging hardware to charge via proximity to a charging field. In one embodiment, power source 702 can include an internal battery or fuel cell source.

Thus, a standalone DIMM cover such as those disclosed herein can provide structural support and stability to tall DIMMs to mitigate the shock and vibration risks associated with taller DIMMs. Note that although the term cover is used in examples throughout this disclosure for ease of reference, the apparatus described herein may only partially cover tops of one or more DIMMs. A standalone DIMM cover may be provided separately from DIMMs, as a kit (e.g., a separate cover and DIMMs to be assembled), or attached to the DIMMs in a system. In one example, one or more dummy DIMMs may be provided to fill spaces under a DIMM cover to provide structural support in a system with fewer DIMMs than a DIMM cover is configured to cover.

Examples of standalone DIMM covers follow.

Example 1: An apparatus including: a standalone rigid body to at least partially cover a plurality of dual inline memory modules (DIMMs), a plurality of grooves in a bottom of the standalone rigid body, each of the plurality of grooves to receive a top edge of one of the plurality of DIMMs, and one or more fasteners to secure the standalone rigid body over the plurality of DIMMs.

Example 2: The apparatus of example 1, wherein the one or more fasteners include: a latch proximate to each of four corners of the standalone rigid body.

Example 3: The apparatus of example 1 or 2, wherein: the standalone rigid body includes four sides, including two sides parallel to the plurality of DIMMs and two sides perpendicular to the plurality of DIMMs.

Example 4: The apparatus of any of examples 1-3 wherein: the standalone rigid body includes a solid top.

Example 5: The apparatus of any of examples 1-3, wherein: the standalone rigid body includes an opening between opposing sides of the standalone rigid body to expose the partially covered plurality of DIMMs.

Example 6: The apparatus of example 5, wherein: the standalone rigid body includes a frame including the opening at its middle.

Example 7: The apparatus of any of examples 1-6, wherein the standalone rigid body includes: a plurality of openings between opposing sides of the standalone rigid body; and one or more supports extending along an axis perpendicular to a length of the plurality of DIMMs.

Example 8: The apparatus of any of examples 1-7, wherein the standalone rigid body includes: a plurality of openings between opposing sides of the standalone rigid body; and one or more supports extending along one or more axes, including one or more of: a first axis perpendicular to a length of the plurality of DIMMs, a second axis parallel to the length of the plurality of DIMMs, and a third axis diagonal relative to the length of the plurality of DIMMs.

Example 9: The apparatus of examples 1-8, wherein: the one or more fasteners include one or more of: latches, screws, and snap attachment mechanisms.

Example 10: The apparatus of any of examples 1-9, wherein: the standalone rigid body has a width to at least partially cover at least two DIMMs.

Example 11: The apparatus of any of examples 1-10, wherein: the standalone rigid body has a width to cover three or more DIMMs.

Example 12: The apparatus of any of examples 1-11, further including: a dummy DIMM to occupy a DIMM slot and corresponding groove of the plurality of grooves.

Example 13: The apparatus of any of examples 1-12, further including: one or more additional rigid bodies, each of the one or more additional rigid bodies to at least partially cover the same or a different plurality of DIMMs of an array of DIMMs.

Example 14: A kit including: a plurality of dual inline memory modules (DIMMs); and a standalone DIMM cover including: a rigid body having a length to at least partially cover two or more DIMMs; a plurality of grooves in a bottom of the rigid body to receive top edges of the two or more DIMMs; and one or more fasteners to secure the rigid body over the two or more DIMMs.

Example 15: The kit of example 14, wherein: the rigid body includes four corners.

Example 16: The kit of example 15, wherein the one or more fasteners includes a latch at each of the four corners of the rigid body.

Example 17: The kit of any of examples 14-16, wherein the rigid body includes four sides, including two sides parallel to the plurality of DIMMs and two sides perpendicular to the plurality of DIMMs.

Example 18: The kit of any of examples 14-16, wherein the standalone DIMM cover is in accordance with any of examples 1-13.

Example 19. A system including: a motherboard including a plurality of dual inline memory module (DIMM) slots, and a standalone DIMM cover including: a rigid body having a length to at least partially cover two or more DIMMs; a plurality of grooves in a bottom of the rigid body to receive top edges of the two or more DIMMs; and one or more fasteners to secure the rigid body over the two or more DIMMs.

Example 20: The system of example 19, further including: a plurality of 2U DIMMs.

Example 21: The system of any of examples 19-20, wherein: the rigid body includes four corners.

Example 22: The system of any of examples 19-21, wherein the standalone DIMM cover is in accordance with any of examples 1-13.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

The hardware design embodiments discussed above may be embodied within a semiconductor chip and/or as a description of a circuit design for eventual targeting toward a semiconductor manufacturing process. In the case of the later, such circuit descriptions may take of the form of a (e.g., VHDL or Verilog) register transfer level (RTL) circuit description, a gate level circuit description, a transistor level circuit description or mask description or various combinations thereof. Circuit descriptions are typically embodied on a computer readable storage medium (such as a CD-ROM or other type of storage technology).

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus comprising:
a standalone rigid body to at least partially cover a plurality of dual inline memory modules (DIMMs);
a plurality of grooves in a bottom of the standalone rigid body, each of the plurality of grooves to receive a top edge of one of the plurality of DIMMs; and
one or more fasteners to secure the standalone rigid body over the plurality of DIMMs.

2. The apparatus of claim 1, wherein the one or more fasteners comprise:
a latch proximate to each of four corners of the standalone rigid body.

3. The apparatus of claim 1, wherein:
the standalone rigid body includes four sides, including two sides parallel to the plurality of DIMMs and two sides perpendicular to the plurality of DIMMs.

4. The apparatus of claim 1, wherein:
the standalone rigid body includes a solid top.

5. The apparatus of claim 1, wherein:
the standalone rigid body includes an opening between opposing sides of the standalone rigid body to expose the partially covered plurality of DIMMs.

6. The apparatus of claim 5, wherein:
the standalone rigid body includes a frame including the opening at its middle.

7. The apparatus of claim 1, wherein the standalone rigid body includes:
a plurality of openings between opposing sides of the standalone rigid body; and
one or more supports extending along an axis perpendicular to a length of the plurality of DIMMs.

8. The apparatus of claim 1, wherein the standalone rigid body includes:
a plurality of openings between opposing sides of the standalone rigid body; and
one or more supports extending along one or more axes, including one or more of: a first axis perpendicular to a length of the plurality of DIMMs, a second axis parallel to the length of the plurality of DIMMs, and a third axis diagonal relative to the length of the plurality of DIMMs.

9. The apparatus of claim 1, wherein:
the one or more fasteners include one or more of: latches, screws, and snap attachment mechanisms.

10. The apparatus of claim 1, wherein:
the standalone rigid body has a width to at least partially cover at least two DIMMs.

11. The apparatus of claim 1, wherein:
the standalone rigid body has a width to cover three or more DIMMs.

12. The apparatus of claim 11, further comprising:
a dummy DIMM to occupy a DIMM slot and corresponding groove of the plurality of grooves.

13. The apparatus of claim 1, further comprising:
one or more additional rigid bodies, each of the one or more additional rigid bodies to at least partially cover the same or a different plurality of DIMMs of an array of DIMMs.

14. A kit comprising:
a plurality of dual inline memory modules (DIMMs); and
a standalone DIMM cover including:
a rigid body having a length to at least partially cover two or more DIMMs;
a plurality of grooves in a bottom of the rigid body to receive top edges of the two or more DIMMs; and
one or more fasteners to secure the rigid body over the two or more DIMMs.

15. The kit of claim 14, wherein:
the rigid body includes four corners.

16. The kit of claim 15, wherein the one or more fasteners comprise:
a latch at each of the four corners of the rigid body.

17. The kit of claim 14, wherein:
the rigid body includes four sides, including two sides parallel to the plurality of DIMMs and two sides perpendicular to the plurality of DIMMs.

18. A system comprising:
a motherboard including a plurality of dual inline memory module (DIMM) slots; and
a standalone DIMM cover including:
a rigid body having a length to at least partially cover two or more DIMMs;
a plurality of grooves in a bottom of the rigid body to receive top edges of the two or more DIMMs; and
one or more fasteners to secure the rigid body over the two or more DIMMs.

19. The system of claim 18, further comprising:
a plurality of 2U DIMMs.

20. The system of claim 18, wherein:
the rigid body includes four corners.
